(19) United States
(12) Patent Application Publication
(10) Pub. No.: US 2009/0302323 A1
(43) Pub. Date: Dec. 10, 2009

(54) Method and apparatus for providing a low-level interconnect section in an imager device

(75) Inventors: Zhiping Yin, Boise, ID (US); Xiangli Li, San Jose, CA (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 12/155,455

(22) Filed: Jun. 4, 2008

(51) Int. Cl. H01L 31/112; H01L 31/18

(52) U.S. Cl. 257/72; 438/73; 257/E31.073

(57) ABSTRACT

Imager pixels with low-level interconnect sections, methods of assembling imager pixels with low-level interconnect sections, and systems containing imager pixels with low-level interconnect sections. Imager pixels are formed such that specific interconnections between transistors and other components of an imager array are removed from one or more upper level metallization sections and placed on a low-level interconnect section closer to the photodetector, such that one upper metallization section is eliminated.

### BACKGROUND OF THE INVENTION

As pixel sizes in solid state imagers shrink, quantum efficiency also decreases. Part of the reduction in quantum efficiency is due to the high aspect ratio of the pixel photodetectors. The aspect ratio of an individual photodetector is a measure of the ratio of the height of an optical path within an imager (light path through a pixel imager cell to a photodetector) to the horizontal cross-sectional area of the optical path. As the height through which light must travel increases, relative to the cross-sectional area of the optical path, quantum efficiency decreases. As pixel size has decreased, so has the cross-sectional area of the optical path and quantum efficiency.

Another method to improve the aspect ratio, and thereby improve quantum efficiency, is to increase the cross-sectional area of the optical path. Ideally, the optical path would have the largest cross-sectional area allowed by the pixel photodetector size. In such a case, the optical path's cross-sectional area would be unobstructed from the microlens to the photodetector. An unobstructed optical path would result in the aspect ratio being determined only by the cross-sectional area of the photodetector, and optical path height. In most cases, however, the cross-sectional area of the optical path is not determined solely by photodetector size, but also by encroachment of metallization sections into the optical path.

The need for metallization sections to route signals to and from various electrical pixels not only increases optical path height, it decreases the available cross-sectional area of the optical path. Although positioned to minimize their intrusion, even minimal metallization section encroachments are significant when considered as percentages of photodetector size. Optical path encroachment is made worse by the accumulation of losses resulting from multiple metal sections being collectively greater than any loss caused by a single metallization section. If the cross-sectional area of the optical path can be improved by either removing metallization sections, or reducing the impact metallization sections have on the optical path's cross-sectional area, then quantum efficiency can be improved.

What is needed, therefore, is an apparatus having an optical path with both a reduced height and increased cross-sectional area, and a method for fabricating such an apparatus.

### BRIEF DESCRIPTION OF THE DRAWINGS

FIG. 1 is a cross-sectional view of a portion of a conventional pixel.

FIG. 2 is a cross-sectional view of a portion of a pixel with a low-level interconnect section and a reduced stack height in accordance with a disclosed embodiment.

FIG. 3A is a schematic diagram of two four-transistor pixels in a row of a pixel array and inter-pixel and intra-pixel signal path connections occurring on a low-level interconnect section in accordance with a disclosed embodiment.

FIG. 3B is a schematic diagram of two four-transistor pixels in a row of a pixel array and inter-pixel and intra-pixel signal path connections occurring on a low-level interconnect section in accordance with a disclosed embodiment, including a reset transistor output interconnect.

FIG. 4A is a schematic diagram of two three-transistor pixels in a row of a pixel array and inter-pixel and intra-pixel signal path connections occurring on a low-level interconnect section in accordance with a disclosed embodiment.

FIG. 4B is a schematic diagram of two three-transistor pixels in a row of a pixel array and inter-pixel and intra-pixel signal path connections occurring on a low-level interconnect section in accordance with a disclosed embodiment, including a reset transistor output interconnect.

FIG. 5 is a schematic diagram of a shared four-transistor pixel showing pixels in two rows and two columns of a pixel array and inter-pixel and intra-pixel signal connections in accordance with a disclosed embodiment.

FIG. 6 is an overhead view of a low-level interconnect section of a shared four-transistor pixel showing pixels in rows and columns of a pixel array and inter-pixel and intra-pixel signal connections in accordance with a disclosed embodiment.

FIG. 7 is a block diagram of an example of an imaging device which may employ pixels according to various disclosed embodiments.

FIG. 8 is a diagram of a system which may employ pixels according to various disclosed embodiments.

### DETAILED DESCRIPTION OF THE INVENTION

In the following detailed description, reference is made to the accompanying drawings, which form a part hereof and illustrate specific embodiments that may be practiced. In the drawings, like reference numerals describe substantially similar components throughout the several views. These embodiments are described in sufficient detail to enable those skilled in the art to practice them, and it is to be understood that structural, logical, and electrical changes may be made.

The term “substrate” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. In addition, the semiconductor need not be silicon-based, but could be based on other semiconductor materials, e.g., silicon-germanium, germanium, or gallium arsenide.

The term “pixel” refers to a picture element unit cell containing a photodetector for converting light radiation to an electrical signal. For purposes of illustration, a representative pixel is illustrated in the figures and description herein and, typically, fabrication of all pixels in an imager will proceed simultaneously in a similar fashion. The following detailed description is, therefore, not to be taken in a limiting sense.

It should be understood that reference to a CMOS imager in accordance with the embodiments disclosed herein is made for the sole purpose of describing just one example of these embodiments. It should be readily apparent that the embodiments disclosed herein are not limited to CMOS imagers or to the specific CMOS imager structures described herein, but also apply to CCD and other imagers that include upper level metallization sections.

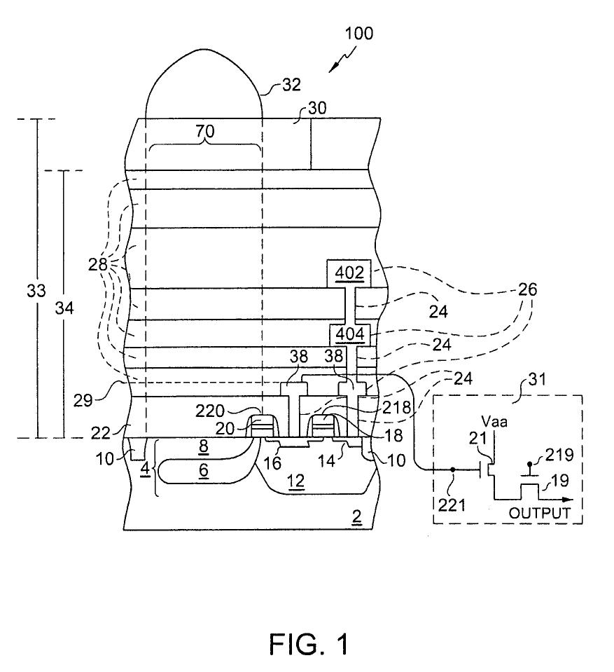

FIG. 1 illustrates a portion of an imager that includes a conventional four transistor CMOS pixel 100. Pixel 100 typically includes a photodetector 4, which may be in the form of a photodiode, having a p-region 8 and an n-region 6 in a p-substrate 2, a transfer transistor 20 with associated gate 220, a storage node 16 formed in a p-type well 12, and a reset transistor 18 with associated gate 218. These pixel structures are covered by a first transparent insulating layer 22. A readout circuit 31, as an electrical schematic circuit, is electrically connected to a conductive plug 24 which connects to the storage node 16. Photons striking the surface of the p-region 8 of the photodetector 4 generate electrons that are collected in the n-region 6. From n-region 6, the accumulated charge is transferred to a storage node 16 and from there it is read out by read out circuit 31 which includes a source follower transistor 21 with associated gate 221, and a row select transistor 19 with associated gate 219. Pixel 100 is shown with a first upper level metallization section 404, a second upper level metallization section 402, and a low-level interconnect section 38, though more upper level metallization sections 26 may be necessary in more complex pixels 100 and associated imager circuits.

The circuitry comprising various plugs 24 and metallization sections 26 interconnects structures within the pixel 100 and structures of the pixel 100 to other circuitry which supplies signals to or takes a readout signal from pixel 100. Pixel 100 further comprises trench isolation regions 10 formed in p-substrate 2 to isolate adjacent pixels 100. A color filter 30 is typically formed on top of the pixel 100 and substantially over photodetector 4. A microlens 32 may be provided over color filter 30 to direct incident light towards photodetector 4 through an optical path 70.

As illustrated in FIG. 1, the conventional pixel 100 typically includes three metallization sections 26 formed on or in transparent dielectric layers 28. Cumulatively, these metallization sections 26 and transparent dielectric layers 28 contribute to the stack height 34, and the stack height 34 is the main component of the optical-path height 33 of the pixel 100. The transparent dielectric layers 28 are necessary to insulate the metallization sections 26 from one another. As such, stack height 34 is dictated in large part by the number of metallization sections 26. A reduction in pixel size does not reduce the number of transistors or signals, and as such does not reduce the stack height 34. In short, stack height 34 does not scale with pixel size. For example, the stack height 34 of a 5.6μ pixel, a 3.6μ pixel, and a 2.8μ pixel is approximately the same, despite reduced pixel size. Pixel size reduction, however, does result in the area of the pixel 100 optical path 70 horizontal cross-section, e.g., along horizontal plane 29, being smaller.

Embodiments described herein reduce the number of metallization sections 26 required in an imager device to reduce stack height 34 and improve the aspect ratio of the optical path 70, thereby improving quantum efficiency.

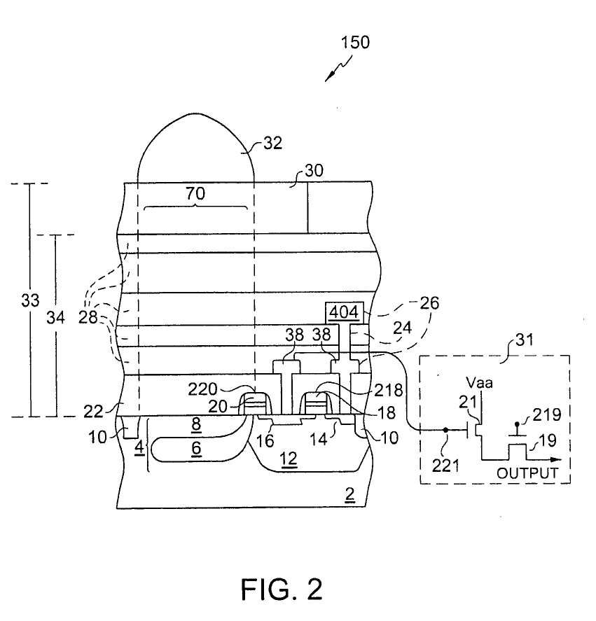

Referring now to FIG. 2, the optical-path height 33 of the FIG. 2 pixel 150 is reduced when compared to the optical path height 33 of FIG. 1 pixel 100 because the second upper level metallization section 402 (FIG. 1), and its associated plugs 24 (FIG. 1), are eliminated. Interconnect components of upper level metallization sections which are required for pixel circuit operation are placed at the low-level interconnect section 38 provided over transparent insulating layer 22. As a consequence, stack height 34 and optical-path height 33 are reduced, necessarily resulting in a lower aspect ratio and improved quantum efficiency.

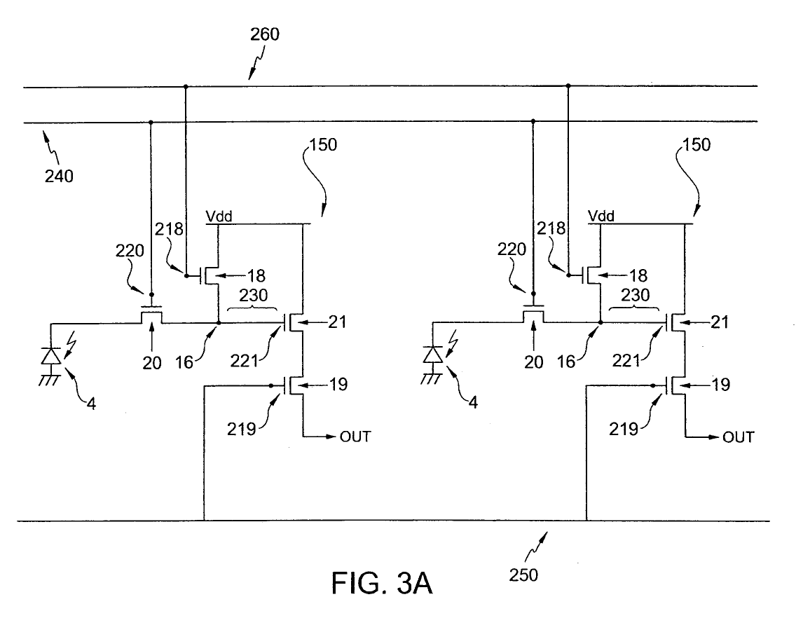

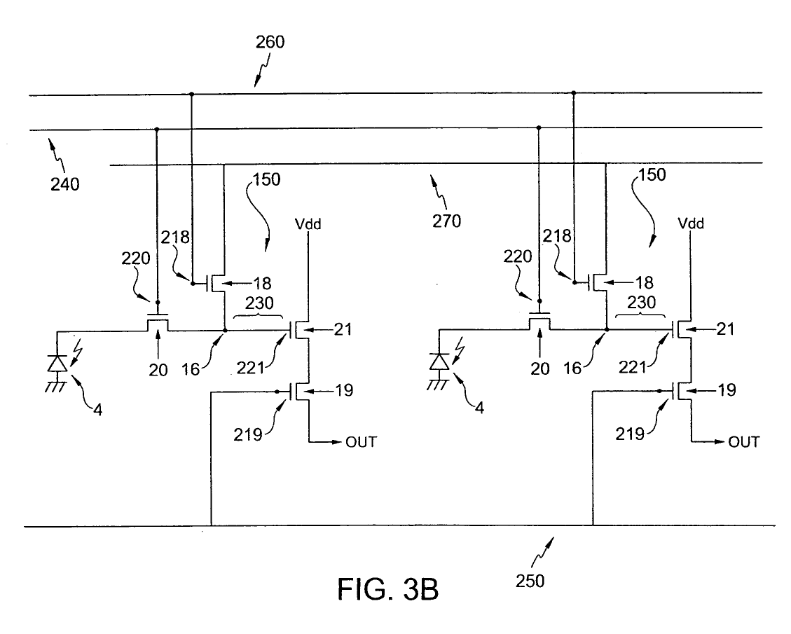

FIG. 3A schematically represents the interconnects 230, 240, 250, 260 present for two adjacent columns of four-transistor CMOS pixels 150. The four interconnects 230, 240, 250, 260 may be moved from an upper level metallization section 402, 404 (FIG. 1) to an alternative connection on the low-level interconnect section 38 (FIG. 2). The interconnects 230, 240, 250, 260 placed at the low-level interconnect section 38 (FIG. 2) include: the source follower transistor 21 gate 221 to the storage node 16 interconnect 230; the transfer transistor 20 gates 220 interconnect 240 between adjacent columns of pixels; the row select transistor 19 gates 219 interconnect 250 between adjacent columns of pixels; and the reset transistor 18 gates 218 interconnect 260 between adjacent columns of pixels. Interconnects 240, 250 and 260 extend across a row of pixels, while interconnect 230 is a local interconnect. All four interconnects 230, 240, 250, and 260, may be moved to the low-level interconnect section 38 (FIG. 2). Alternatively, embodiments may include moving any combination of interconnects 240, 250, 260 with interconnect 230 to the low-level interconnect section 38 (FIG. 2).

FIG. 3B is similar to FIG. 3A, except that four-transistor pixel 150 has an interconnect 270 between adjacent columns of pixels connecting the reset transistor 18 outputs. All five interconnects 230, 240, 250, 260, 270 may be moved to the low-level interconnect section 38 (FIG. 2), or embodiments may include moving any combination of interconnects 240, 250, 260, 270 with interconnect 230 to the low-level interconnect section 38 (FIG. 2).

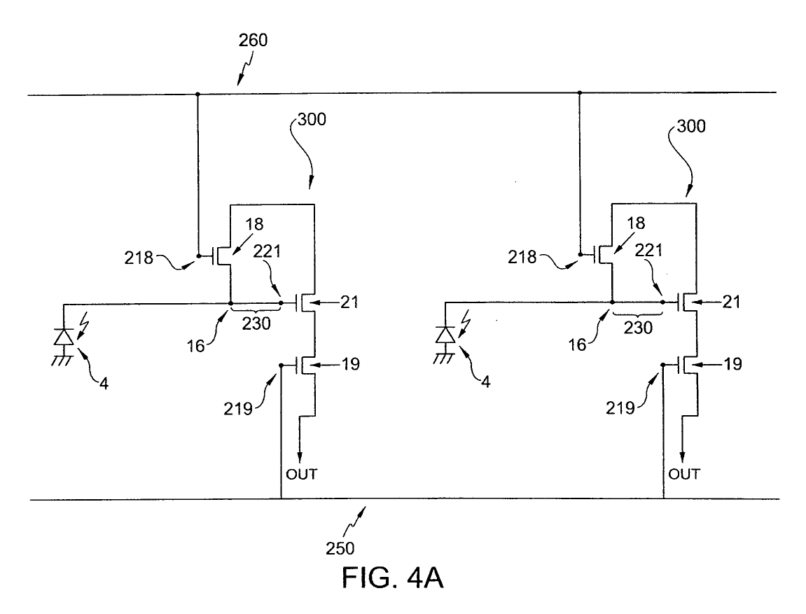

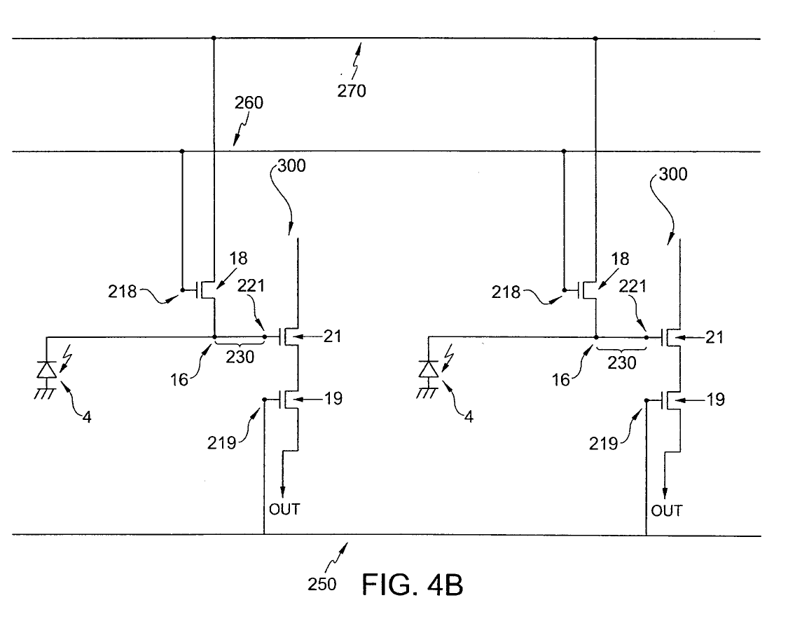

FIG. 4A schematically represents the interconnects 230, 250, 260 present for two adjacent columns of a pixel array employing three-transistor pixels 300. FIG. 4A is similar to FIG. 3A except that pixel 300 does not include a transfer transistor 20 (FIG. 3A). In this embodiment there is no interconnect 240 (FIG. 3A) so only interconnects 230, 250, 260 are present at the low-level interconnect section 38 (FIG. 2). All three interconnects 230, 250, 260 may be moved to the low-level interconnect section 38 (FIG. 2), or embodiments may include moving any combination of interconnects 250, 260 with interconnect 230 to the low-level interconnect section 38 (FIG. 2).

FIG. 4B schematically represents the interconnects 230, 250, 260 present in FIG. 4A, but also presents interconnect 270. FIG. 4B is similar to FIG. 3B except that pixel 300 does not include a transfer transistor 20 (FIG. 3A), so there is no interconnect 240 (FIG. 3A). As for FIG. 4A, all four interconnects 230, 250, 260, 270 may be moved to the low-level interconnect section 38 (FIG. 2), or embodiments may include moving any combination of interconnects 250, 260, 270 with interconnect 230 to the low-level interconnect section 38 (FIG. 2).

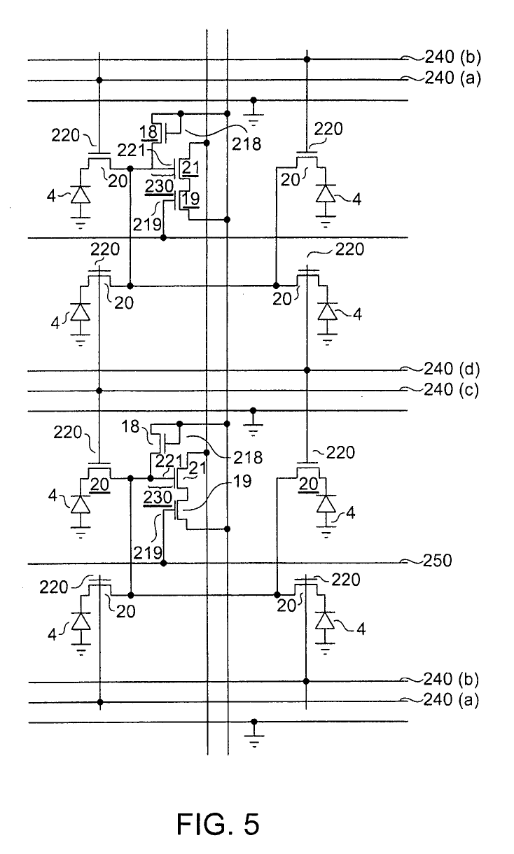

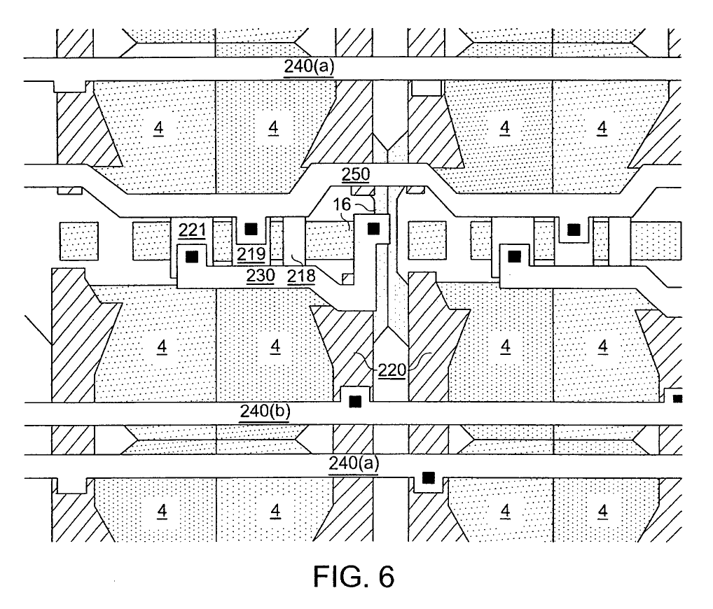

FIG. 5 schematically represents the interconnects 230, 240, 250 for four way shared CMOS pixels where the reset transistor 18, row select transistor 19, and source follower transistor 21 are shared among four pixels. For each group of four pixels with the shared transistors 18, 19, 21, there is a single source follower transistor 21 gate 221 to the storage node 16 interconnect 230, and a single row select transistor 19 gates 219 interconnect 250 for the group of four pixels. There are, however, four transfer transistor 20 gates 220 interconnects 240(a), 240(b), 240(c), 240(d). Each interconnect 240(a), 240(b), 240(c), 240(d) controls one transfer transistor 20 from a first group of four way shared CMOS pixels, and also controls one transfer transistor 20 from an adjacent group of four way shared CMOS pixels. In this embodiment the low-level interconnect section 38 may contain 230 and 240, 230 and 250, 240 and 250, or 230, 240, and 250. FIG. 6 is an overhead view of the shared four transistor CMOS pixels of FIG. 5, and shows the 230, 240(a), 240(b), and 250 interconnects all provided on a low-level interconnect section 38 which is the first metallization section 26 above the transistors and their associated gates.

Although embodiments have been described as applicable to four-transistor 150, three-transistor 300 pixels, and shared four transistor pixels, the embodiments disclosed herein may be incorporated into other known pixel designs having a different number of transistors, e.g. five transistor (5T), six transistor (6T), etc.

Another method to improve the aspect ratio is by increasing the horizontal cross-sectional area of the optical path 70. Accordingly, to further improve the aspect ratio of an optical path 70, tungsten is used at the low-level interconnect section 38 to create tighter tolerances. Using tungsten, as opposed to using another conductor such as aluminum, allows for an optical path 70 with a greater horizontal cross-sectional area, because an identical connection with tungsten allows for both smaller connections, and the ability to place interconnections closer to each other. Additionally, using a low-level interconnect section 38 which includes signal paths previously included on upper metallization sections 402, 404, completely eliminates one metallization section 26. Eliminating the second metallization section 402 results in removing one entire source of optical path 70 encroachment.

The location of a low-level interconnect section 38 is limited by the height of the transistor gates 218, 219, 220, 221 which are covered by the first transparent insulating layer 22. The low-level interconnect section 38 is not limited to being located immediately over the first transparent insulating layer 22, it only need reside some distance below a first upper level metallization section 404. The low-level interconnect section 38 can be at any level starting at approximately 140 nm above substrate 2, which is a level above the pixel transistor gates, through a level ending at approximately 350 nm above substrate 2. The low-level interconnect section 38 may also be placed on or within the first transparent insulating layer 22, so long as its placement within the first transparent insulating layer 22 is within the approximately 140 nm to approximately 350 nm range above the substrate 2.

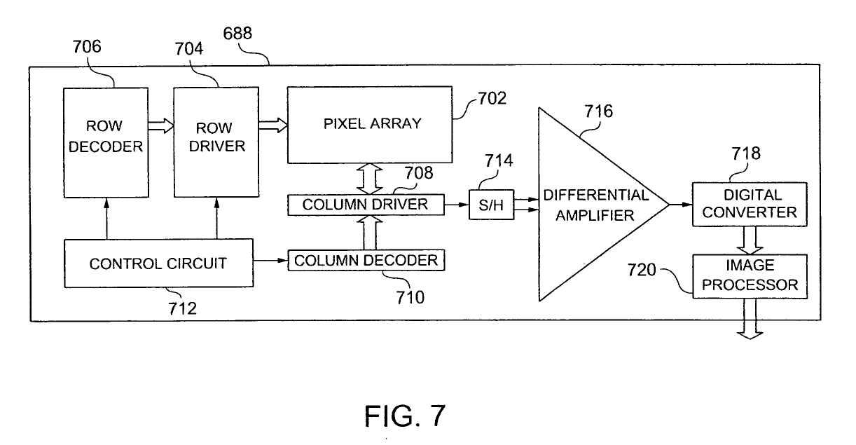

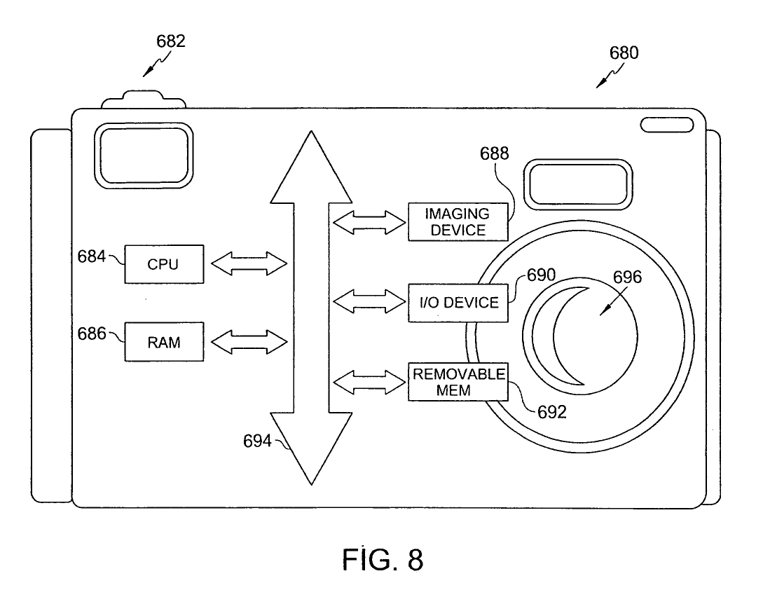

Referring to FIG. 7, an imager 688, for example, a CMOS imager, for use with the system 680 (FIG. 8) is shown. The imager 688 has a pixel array 702 comprising a plurality of pixels arranged in a predetermined number of columns and rows. Attached to the array 702 is signal processing circuitry. The pixels of each row in array 702 are all turned on at the same time by a row select line, and the pixels of each activated row are selectively output by respective column select lines. A plurality of row and column select lines are provided for the entire array 702. The row lines are selectively activated by a row driver 704 in response to row address decoder 706. The column select lines are selectively activated by a column driver 708 in response to column address decoder 710. Thus, a row and column address is provided for each pixel.

The imager 688 is operated by the timing and control circuit 712, which controls address decoders 706, 710 for selecting the appropriate row and column lines for pixel readout. The control circuit 712 also controls the row and column driver circuitry 704, 708 such that they apply driving voltages to the drive transistors of the selected row and column select lines. The pixel column signals, which for a CMOS imager pixel typically include a pixel reset signal (Vᵣₛₜ) and a pixel image signal (V_{sig}), are read by a sample and hold circuit 714. Vᵣₛₜ is read from a pixel immediately after a charge storage region is reset. V_{sig} represents the amount of charges generated by the pixel's photosensitive element and stored in the storage node 16 (FIG. 1) in response to applied light to the pixel. A differential signal of Vᵣₛₜ and V_{sig} is produced by differential amplifier 716 for each pixel. The differential signal is digitized by analog-to-digital converter 718 (ADC). The analog-to-digital converter 718 supplies the digitized pixel signals to an image processor 720, which forms and outputs a digital image.

Referring to FIG. 8, a typical system 680 which may use an imager is shown, such as, for example, a camera. The system 680 includes an imaging device 688 having an imager pixel 150 (FIG. 2). The system 680 is an example of a system having digital circuits that could include image sensor devices. Without being limiting, such a system could include a computer system, camera system (as shown), scanner, machine vision, vehicle navigation system, video phone, surveillance system, auto focus system, star tracker system, motion detection system, image stabilization system, and other systems employing an imager.

System 680, for example, a still or video camera system, includes a lens 96 for focusing an image when a shutter release button 682 is pressed. System 680 generally comprises a central processing unit (CPU) 684, such as a microprocessor that controls camera functions and image flow, and communicates with an input/output (I/O) device 690 over a bus 694. The imaging device 688 also communicates with the central processing unit 684 over the bus 694. The processor-based system 680 also includes random access memory (RAM) 686, and can include removable memory 692, such as flash memory, which also communicates with the central processing unit 684 over the bus 694. The imaging device 688 may be combined with the central processing unit 684, with or without memory storage on a single integrated circuit or on a different chip than the central processing unit 684.

Although embodiments have been described with reference to use in CMOS imagers, they are also applicable to other imagers, for example, CCD and others.

The above description and drawings illustrate embodiments which achieve the objects, features, and advantages described. Although certain advantages and embodiments have been described above, those skilled in the art will recognize that substitutions, additions, deletions, modifications and/or other changes may be made.

What is claimed as new and desired to be protected by Letters Patent of the United States is:

1. An imager device comprising:
a pixel array having a plurality of pixels arranged in rows and columns, each of the pixels comprising:
a photodetector;
a storage node that stores charges from the photodetector;
at least one transistor that controls an operation of the pixel;
an insulating material residing over the pixel array to cover the transistor; and
a control line which extends across the pixel array in a row-wise direction, the control line residing at a first metal section within the pixel array and connected to a gate of the transistor through a conductive via in the insulating material.

2. An imager device as in claim 1 wherein the transistor is a transfer transistor that controls transfer of charge from the photodetector to the storage node.

3. An imager device as in claim 1 wherein the transistor is a row select transistor that controls an output from at least one pixel of the pixel array.

4. An imager device as in claim 1 wherein each one of the pixels further comprise:
a transistor that provides an output signal based on charges at the storage node; and
an interconnect at the first metal section that interconnects the storage node to a gate of the transistor that provides an output signal, wherein the interconnect connects to the storage node and gate through respective conductive vias in the insulating material.

5. An imager device as in claim 1 wherein the transistor is a reset transistor that resets the storage node, and wherein the control line is connected to a gate structure of the transistor.

6. An imager device as in claim 1 wherein the transistor is a reset transistor that resets the storage node, and wherein the control line is connected to an output node of the transistor.

7. An imager device as in claim 1 wherein each one of the pixels further comprise:
a transistor that provides an output signal based on charges at the storage node; and
an interconnect at the first metal section to interconnect the storage node to a gate of the transistor that provides an output signal, wherein the interconnect connects to the storage node and gate through respective conductive vias in the insulating material, and wherein the transistor that controls an operation of the pixel is a transfer transistor that controls transfer of charge from the photodetector to the storage node.

8. An imager device as in claim 1 wherein each one of the pixels further comprise:
a transistor that provides an output signal based on charges at the storage node; and
an interconnect at the first metal section to interconnect the storage node to a gate of the transistor that provides an output signal, wherein the interconnect connects to the storage node and gate through respective conductive vias in the insulating material, and wherein the transistor that controls an operation of the pixel is a row select transistor that controls an output from the pixel.

9. An imager device as in claim 1 wherein each one of the pixels further comprise:
a transistor that provides an output signal based on charges at the storage node; and
an interconnect at the first metal section to interconnect the storage node to a gate of the transistor that provides an output signal, wherein the interconnect connects to the storage node and gate through respective conductive vias in the insulating material, and wherein the transistor that controls an operation of the pixel is a reset transistor that resets the storage node, and wherein the control line is connected to a gate structure of the resent transistor.

10. An imager device as in claim 1 wherein each one of the pixels further comprise:
a transistor that provides an output signal based on charges at the storage node; and
an interconnect at the first metal section to interconnect the storage node to a gate of the transistor that provides an output signal, wherein the interconnect connects to the storage node and gate through respective conductive vias in the insulating material, and wherein the transistor that controls an operation of the pixel is a reset transistor that resets the storage node, and wherein the control line is connected to an output node of the reset transistor.

11. An imager device as in claim 1 wherein the photodetectors are formed in a substrate and the first metal section resides between about 140 nm and about 350 nm above the substrate.

12. An imager device as in claim 1 wherein each one of the pixels further comprises:
a transistor that provides an output signal based on charges at the storage node;
an interconnect at the first metal section to interconnect the storage node to a gate of the transistor that provides an output signal, wherein the interconnect connects to the storage node and gate through respective conductive vias in the insulating material, and wherein the transistor that controls an operation of the pixel is a transfer transistor that controls transfer of charge from the photodetector to the storage node; and
a second control line which extends across a pixel array in a row-wise direction, the second control line residing at the first metal section within the pixel array and connected to a gate of a row select transistor through a conductive via in the insulating material.

13. An imager device comprising a pixel array comprising:
a plurality of pixel groups, the pixels arranged in rows and columns, each of the pixels in a group comprising:
a photodetector and a transfer transistor that controls transfer of charge from the photodetector to a storage node;
a plurality of first control lines at a first metal section within the pixel array and extending across the pixel array in a row-wise direction, the first control line being connected to a gate of at least one transfer transistor, and wherein the control lines are connected through a conductive via in the insulating material;
a row select transistor that controls an output from the pixel group; and
a second control line residing at the first metal section within the pixel array extending across the pixel array in a row-wise direction, the second control line being connected to a gate of the row select transistor through a conductive via in the insulating material.

14. The imager device of claim 13 wherein each of the pixel groups further comprise:
a transistor that provides an output signal based on charges at the storage node; and
an interconnect at the first metal section to interconnect the storage node to a gate of the transistor that provides an output signal, wherein the interconnect connects to the storage node and gate through respective conductive vias in the insulating material.

15. The imager device of claim 14 wherein the photodetectors are formed in a substrate and the first metal section resides between about 140 nm and about 350 nm above the substrate.

16. A method of forming a pixel array comprising a plurality of pixels arranged in rows and columns, the method comprising:
forming a plurality of photodetectors;
forming at least one storage node that receives charges from at least one of the photodetectors;
forming at least one transistor that controls an operation of at least one pixel;
forming an insulating material over the pixel array to cover the transistor; and
forming a first metal section comprising a control line connecting the pixel array in a row-wise direction, wherein the control line is connected to gates of the transistors through a conductive via in the insulating material.

17. A method of forming a pixel array as in claim 1.6 wherein the transistors are transfer transistors that control a charge transferred from a photodetector to a storage node.

18. A method of forming a pixel array as in claim 16 wherein the transistors are row select transistors that control outputs from at least one pixel of the pixel array.

19. A method of forming a pixel array as in claim 16 further comprising:
forming transistors that provide output signals based on charges at associated storage nodes; and
forming a plurality of interconnects at the first metal section that connect respective storage nodes to the associated gates of the transistors that provide an output signal, wherein the plurality of interconnects connect to the storage nodes and transistor gates through conductive vias in the insulating material.

20. A method of forming a pixel array as in claim 16 wherein the transistors are reset transistors that reset the storage node, and wherein the control line is connected to a gate structure of the transistor.

21. A method of forming a pixel array as in claim 16 wherein the transistors are reset transistors that reset the storage node, and wherein the control line is connected to an output node of the transistor.

22. A method of forming a pixel array as in claim 16 further comprising:
forming transistors that provide output signals based on charges at associated storage nodes; and
forming the first metal section to further comprise interconnects that connect the storage nodes to associated gates of the transistors that provide output signals, wherein the interconnects connect to the storage nodes and gates through conductive vias in the insulating material, and wherein the transistors that control an operation of their respective pixels are transfer transistors that control charge transfer from photodetectors to storage nodes.

23. A method of forming a pixel array as in claim 16 further comprising:
forming transistors that provide output signals based on charges at associated storage nodes; and
forming the first metal section to further comprise interconnects that connect the storage nodes to associated gates of the transistors that provide output signals, wherein the interconnects connect to the storage nodes and gates through conductive vias in the insulating material, and wherein the transistors that control an operation of their respective pixel are row select transistors that control an output from the pixels.

24. A method of forming a pixel array as in claim 16 further comprising:
forming transistors that provide output signals based on charges at associated storage nodes; and
forming the first metal section to further comprise interconnects that connect the storage nodes to associated gates of the transistors that provide output signals, wherein the interconnects connect to the storage nodes and gates through conductive vias in the insulating material, and wherein the transistors that control an operation of their respective pixels are reset transistors that reset the storage node, and wherein the control line is connected to gate structures of the reset transistors.

25. A method of forming a pixel array as in claim 16 further comprising:
forming transistors that provide output signals based on charges at associated storage nodes; and
forming the first metal section to further comprise interconnects that connect the storage nodes to associated gates of the transistors that provide output signals, wherein the interconnects connect to the storage nodes and gates through conductive vias in the insulating material, and wherein the transistors that control an operation of their respective pixel are reset transistors that reset the storage node, and wherein the control line is connected to output nodes of the reset transistors.

26. A method of forming a pixel array as in claim 16 wherein the photodetectors are formed in a substrate and the first metal section resides between about 140 nm and about 350 nm above the substrate.

27. A method of forming a pixel array as in claim 16 further comprising:
forming transistors that provide output signals based on charges at associated storage nodes;
forming the first metal section to further comprise interconnects that connect the storage nodes to associated gates of the transistors that provide output signals, wherein the interconnects connect to the storage nodes and gates through conductive vias in the insulating material, and wherein the transistors that control an operation of their respective pixels are transfer transistors that control charge transfer from photodetectors to storage nodes; and
forming the first metal section to further comprise a second control line connecting a pixel array in a row-wise direction, wherein the second control line is connected to gates of the row select transistors through a conductive via in the insulating material.

28. A camera system comprising:
an integrated circuit for generating output signals representing a captured image; and
a lens for forming an image on a pixel array, the pixel array comprising a plurality of pixels, each one of the pixels comprising:
a photodetector and a storage node provided on a substrate;
a first transistor that provides an output signal based on charges stored in the storage node;
an insulating layer group provided over the substrate comprising at least one insulating layer; and
an electrical conductor section provided within the insulating layer group such that it resides between about 140 nm and about 350 nm above the substrate, the electrical conductor section comprising:
a first conductive portion connected between a first conductive via through the at least one insulating layer to the storage node, and a second conductive via in the insulating layer group to a gate structure of the transistor that provides an output signal; and
a second conductive portion connected by a third conductive via through the at least one insulating layer to a second transistor to row-wise interconnect like transistors of adjacent pixels.

29. The camera system as in claim 28 wherein the second transistor gates an output signal of the pixel, and wherein the second conductive portion is connected to a gate structure of the second transistor.

30. The camera system as in claim 28 wherein the second transistor electrically interconnects the photodetector and the storage node, and wherein the second conductive portion is connected to a gate structure of the second transistor.

31. The camera system as in claim 29, each one of the pixels further comprising:
a transistor structure that electrically interconnects the photodetector and storage node, and wherein the electrical conductor section further comprises:
a third conductive portion connected by a fourth conductive via through the at least one insulating layer to a gate structure of the transistor structure that electrically interconnects the photodetector, the third conductive portion operating to row-wise interconnect like gates of adjacent pixels.

32. The camera system as in claim 28 wherein the second transistor resets the storage node, and wherein the second conductive portion is connected to a gate structure of the second transistor.

33. The camera system as in claim 28 wherein the second transistor resets the storage node, and wherein the second conductive portion is connected to an output node of the second transistor.

34. The camera system as in claim 30, each one of the pixels further comprising:
a transistor that gates an output signal of the pixel; and
a transistor that resets the storage node, wherein the electrical conductor section further comprises:
a third conductive portion connected by a fourth conductive via through the at least one insulating layer to a gate structure of the transistor structure that gates an output signal of the pixel, the third conductive portion operating to row-wise interconnect like gates of adjacent pixels;
a fourth conductive portion connected by a fifth conductive via through the at least one insulating layer to a gate structure of the transistor that resets the storage node, the fourth conductive portion operating to row-wise interconnect like gates of adjacent pixels; and
a fifth conductive portion connected by a sixth conductive via through the at least one insulating layer to an output node of the transistor that resets the storage node, the fifth conductive portion operating to row-wise interconnect like transistors of adjacent pixels.
